(19) United States
(12) Patent Application Publication
(10) Pub. No.: US 2012/0286411 A1
(43) Pub. Date: Nov. 15, 2012

(54) SEMICONDUCTOR DEVICE AND MANUFACTURING METHOD THEREOF, AND SEMICONDUCTOR MODULE USING THE SAME

(75) Inventors: Takeshi Watanabe, Yokkaichi-shi (JP); Takashi Imoto, Yokkaichi-shi (JP); Naoto Takebe, Yokkaichi-shi (JP); Yuuki Kuro, Mie-gun (JP); Yusuke Doumae, Yokkaichi-shi (JP); Katsunori Shibuya, Yokkaichi-shi (JP); Yoshimune Kodama, Kuwana-shi (JP); Yuji Karakane, Yokkaichi-shi (JP); Masatoshi Kawato, Kameyama-shi (JP)

(73) Assignee: Kabushiki Kaisha Toshiba, Tokyo (JP)

(21) Appl. No.: 13/422,437

(22) Filed: Mar. 16, 2012

(30) Foreign Application Priority Data
May 12, 2011 (JP) 2011-106875

(51) Int. Cl. H01L 25/07; H01L 21/60; H01L 21/98; H01L 23/495

(52) U.S. Cl. 257/676; 438/123; 438/109; 257/E25.018; 257/E23.036; 257/E21.506; 257/E21.705

(57) ABSTRACT

According to one embodiment, there is provided a semiconductor device including a wiring board, a semiconductor chip mounted on a first surface of the wiring board, first external electrodes provided on the first surface of the wiring board, second external electrodes provided on a second surface of the wiring board, and a sealing resin layer sealing the semiconductor chip together with the first external electrodes. The sealing resin layer has a recessed portion exposing a part of each of the first external electrodes. The plural semiconductor devices are stacked to form a semiconductor module with a POP structure. In this case, the first external electrodes of the lower-side semiconductor device and the second external electrodes of the upper-side semiconductor device are electrically connected.

### CROSS-REFERENCE TO RELATED APPLICATION

This application is based upon and claims the benefit of priority from Japanese Patent Application No. 2011-106875, filed on May 12, 2011; the entire contents of which are incorporated herein by reference.

### FIELD

Embodiments described herein relate generally to a semiconductor device and a manufacturing method thereof, and a semiconductor module using the same.

### BACKGROUND

In order to realize miniaturization and high density packaging of a semiconductor device, a staked multichip package in which a plurality of semiconductor chips are stacked and resin-sealed in one package is in practical use. In order to realize further high integration and high function of multichip package, the practical use of semiconductor module having a structure in which semiconductor packages each formed by resin-sealing a plurality of semiconductor chips mounted on a wiring board are sterically stacked, namely, a POP (Package on Package) structure, has been promoted.

In the semiconductor module having the POP structure, for connecting between the plural semiconductor packages, there are used projected electrodes (bump electrodes) made of solder balls provided on a wiring board or a through electrode provided in a sealing resin layer. The formation of the projected electrode is easier than that of the through electrode, so that the projected electrode contributes to the reduction in manufacturing cost of the semiconductor module with the POP structure. When the projected electrodes are used to connect between the plural semiconductor packages, the projected electrodes are disposed around a sealing resin layer that seals the semiconductor chips, and it is required to set a height of the projected electrode to be equal to or more than a height of the sealing resin layer of the lower-side semiconductor package. For this reason, a diameter and a formation pitch of the projected electrode (solder ball) tend to become large. This becomes a main cause because of which miniaturization and increase in the number of input/output pins in the semiconductor module are prevented, and it is not possible to deal with an increase in the number of stacking of semiconductor chips in the semiconductor package.

### BRIEF DESCRIPTION OF THE DRAWINGS

FIG. 1 is a sectional view showing a semiconductor device according to a first embodiment.

FIG. 2 is a sectional view showing a semiconductor device according to a second embodiment.

FIG. 3A to FIG. 3G are sectional views showing manufacturing processes of the semiconductor device according to an embodiment.

FIG. 4 is a view showing a first example of a formation process of a sealing resin layer in the manufacturing processes of the semiconductor device shown in FIG. 3A to FIG. 3G.

FIG. 5 is a view showing a second example of the formation process of the sealing resin layer in the manufacturing processes of the semiconductor device shown in FIG. 3A to FIG. 3G.

FIG. 6 is a view showing a third example of the formation process of the sealing resin layer in the manufacturing processes of the semiconductor device shown in FIG. 3A to FIG. 3G.

FIG. 7 is a sectional view showing a semiconductor module according to a first embodiment.

FIG. 8 is a sectional view showing a modified example of the semiconductor module according to the first embodiment.

FIG. 9 is a sectional view showing another modified example of the semiconductor module according to the first embodiment.

FIG. 10 is a sectional view showing a semiconductor module according to a second embodiment.

FIG. 11 is a sectional view showing a semiconductor module according to a third embodiment.

### DETAILED DESCRIPTION

According to one embodiment, there is provided a semiconductor device including a wiring board having a first surface including a chip mounting area and a first wiring layer and a second surface including a second wiring layer electrically connected to the first wiring layer, a semiconductor chip mounted on the first surface of the wiring board and having electrode pads, connection members electrically connecting the first wiring layer and the electrode pads, first external electrodes provided on the first surface of the wiring board and electrically connected to the first wiring layer, second external electrodes provided on the second surface of the wiring board and electrically connected to the second wiring layer, and a sealing resin layer provided on the first surface of the wiring board to seal the semiconductor chip together with the connection members and the first external electrodes and having a recessed portion exposing a part of each of the first external electrodes.

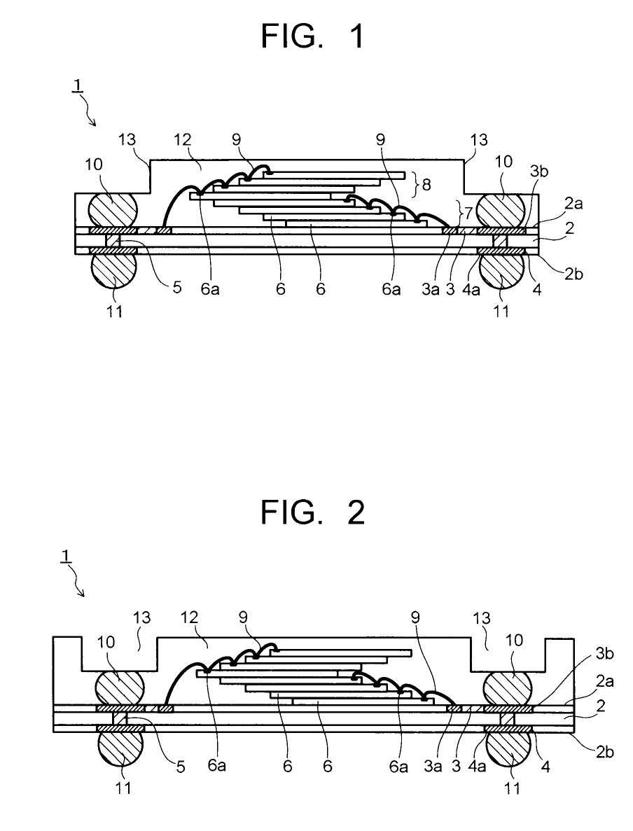

A semiconductor device and a manufacturing method thereof and a semiconductor module using the same of embodiments will be described with reference to the drawings. FIG. 1 is a sectional view showing a semiconductor device according to a first embodiment. FIG. 2 is a sectional view showing a semiconductor device according to a second embodiment. Each of semiconductor devices 1 shown in these drawings includes a wiring board 2. The wiring board 2 has a first surface (upper surface) 2a to be a chip mounting surface, and a second surface (lower surface) 2b to be an external connection surface. The first surface 2a of the wiring board 2 has a chip mounting area provided in the vicinity of a center thereof.

On the first surface 2a of the wiring board 2, a first wiring layer 3 is provided. On the second surface 2b of the wiring board 2, a second wiring layer 4 is provided. It is also possible to provide, according to need, a wiring layer inside the wiring board 2. The first wiring layer 3 and the second wiring layer 4 are electrically connected by a via 5 provided in the wiring board 2. The first wiring layer 3 has first connection pads 3a disposed around the chip mounting area and second connection pads 3b disposed on an outer peripheral side of the first connection pads 3a. The second wiring layer 4 has third connection pads 4a disposed to correspond to the second connection pads 3b. The first connection pads 3a function as connecting portions between the wiring board 2 and a semiconductor chip to be mounted on the wiring board 2. The second and third connection pads 3b, 4a function as forming portions of later-described projected electrodes, and are provided on outer peripheral areas except for the chip mounting area and an area corresponding to the chip mounting area.

On the chip mounting area of the wiring board 2, a semiconductor chip 6 is mounted. The number of semiconductor chips 6 mounted on the wiring board 2 is not particularly limited, and may be one or two or more. FIG. 1 and FIG. 2 show the semiconductor device 1 in which a plurality of semiconductor chips 6, 6 . . . are stacked to be mounted on the chip mounting area of the wiring board 2. As a concrete example of the semiconductor chip 6, a semiconductor memory chip of NAND-type flash memory or the like can be cited, but, the semiconductor chip 6 is not limited to this. Each of the plurality of semiconductor chips 6, 6 . . . has electrode pads 6a arranged along one outer edge.

The plural semiconductor chips 6 are stacked in a stepped manner to expose the electrode pads 6a. In each of the semiconductor devices 1 shown in FIG. 1 and FIG. 2, the plural semiconductor chips 6 are divided into a first chip group 7 and a second chip group 8. Each of the first and second chip groups 7, 8 is formed of four semiconductor chips 6. The four semiconductor chips 6 that form the first chip group 7 are stacked one by one in a stepped manner on the chip mounting area of the wiring board 2. The four semiconductor chips 6 that form the second chip group 8 are stacked one by one in a stepped manner on the first chip group 7. A step direction of the second chip group 8 is an opposite direction to a step direction of the first chip group 7. A direction of edges along which the pads of the first chip group 7 are arranged and a direction of edges along which the pads of the second chip group 8 are arranged are opposite to each other.

The shape of stacking of the semiconductor chips 6 is not limited to the aforementioned step-shape, and it is also possible to adopt a shape of stacking in which the plural semiconductor chips 6 are stacked in a stepped manner in only one direction, and the plural semiconductor chips 6 are stacked so that the directions of edges along which the pads are arranged become alternately opposite to one another. The plural semiconductor chips 6 may also be stacked by aligning the outer edges thereof. In this case, a metal wire as a connection member to be described later is embedded in an adhesive layer that adheres between the plural semiconductor chips 6. It is also possible to stack the semiconductor chips 6 while connecting between the semiconductor chips 6 with fine solder bumps by utilizing through electrodes provided in the semiconductor chips 6. The shape of stacking and the number of stacking of the semiconductor chips 6 are not particularly limited.

The electrode pads 6a of the plural semiconductor chips 6 that form the first chip group 7 are electrically connected to the first connection pads 3a positioned in the vicinity of the electrode pads 6a via metal wires (Au wires or the like) 9. In like manner, the electrode pads 6a of the plural semiconductor chips 6 that form the second chip group 8 are electrically connected to the first connection pads 3a positioned in the vicinity of the electrode pads 6a via the metal wires 9. In the semiconductor chips 6 that form the first and second chip groups 7, 8, the electrode pads 6a having the equal electric property and signal property can be connected one by one by the metal wires 9. The connection members electrically connecting the electrode pads 6a of the semiconductor chip 6 and the first connection pads 3a are not limited to the metal wires 9, and may also be wiring layers (conductor layers) formed by ink-jet printing or the like, or the aforementioned fine solder bumps according to circumstances.

On the second connection pad 3b of the first wiring layer 3, there are formed first projected electrodes (first external electrodes) 10 as first external connection terminals. On the third connection pad 4a of the second wiring layer 4, there are formed second projected electrodes (second external electrodes) 11 as second external connection terminals. As the first and second projected electrodes 10, 11, solder balls are applied, for example. By placing each of the solder balls on the second and third connection pads 3b, 4a and reflowing the solder balls, the first and second projected electrodes 10, 11 made of the solder balls (solder bumps) are formed. The projected electrodes 10, 11 are not limited to the solder balls, and it is also possible to apply a multi-layered body of metal plating film or the like. However, it is preferable to apply the projected electrodes 10, 11 made of the solder balls since it is possible to manufacture the projected electrodes 10, 11 having a certain level of height at a low cost.

On the first surface 2a of the wiring board 2, there is formed a resin sealing layer 12 that seals the semiconductor chips 6 together with the metal wires 9 and the first projected electrodes 10. The semiconductor chips 6 and the metal wires 9 are completely sealed by the resin sealing layer 12, but, in order to make the first projected electrodes 10 function as the external connection terminals, a part of each of the first projected electrodes 10 is exposed from the resin sealing layer 12. The resin sealing layer 12 has a recessed portion 13 exposing a part of each of the first projected electrodes 10. In other words, although a large part of each of the first projected electrodes 10 is embedded in the resin sealing layer 12, a part of each of the first projected electrodes 10 is exposed to the inside of the recessed portion 13 formed from a surface of the resin sealing layer 12 toward the first projected electrodes 10.

As will be described later in detail, the recessed portion 13 is formed by cutting or melting a portion of the resin sealing layer 12 corresponding to the first projected electrodes 10, or by previously providing a projected portion corresponding to the recessed portion 13 on a metal mold for resin sealing. When the recessed portion 13 is formed by cutting or melting a part of the resin sealing layer 12, a part of each of the first projected electrodes 10 is cut or melted together with the resin sealing layer 12, thereby exposing a part of each of the first projected electrodes 10 to the inside of the recessed portion 13 of the resin sealing layer 12. When the metal mold having the projected portion is used, by previously adjusting a height of the projected portion to a height so that the projected portion is brought into contact with the first projected electrodes 10 to form an exposed surface, a part of each of the first projected electrodes 10 is exposed to the inside of the recessed portion 13 formed by the projected portion of the metal mold.

The recessed portion 13 of the semiconductor device 1 shown in FIG. 1 has a shape in which a side surface on an end side of the resin sealing layer 12 is opened. Specifically, the recessed portion 13 shown in FIG. 1 is formed so that the sealing resin layer 12 is removed to part of its end face, resulting in that one side surface is opened. The shape of the recessed portion 13 is not limited to the shape shown in FIG. 1. The recessed portion 13 of the semiconductor device 1 shown in FIG. 2 has a shape of groove in which all side surfaces are formed as wall surfaces. The recessed portion 13 is only required to be formed from the surface of the resin sealing layer 12 toward a depth direction to a position at which a part of each of the first projected electrodes 10 is exposed, without obstructing the resin-sealing state of the semiconductor chips 6 and the metal wires 9.

As will be described later in detail, each height of the first and second projected electrodes 10, 11 is set to a height at which, when a plurality of semiconductor devices 1 are stacked, it is possible to electrically connect between the upper and lower semiconductor devices 1. When the plural semiconductor devices 1 are stacked to form a semiconductor module with the POP structure, by connecting the first projected electrodes 10 of the lower-side semiconductor device 1 and the second projected electrodes 11 of the upper-side semiconductor device 1, the upper and lower semiconductor devices 1 are electrically connected. Therefore, a total height (connection height) of the first projected electrode 10 and the second projected electrode 11 is set to be equal to or more than a thickness of the resin sealing layer 12 of the semiconductor device 1 (height of portion except for the recessed portion 13). For example, each height of the first and second projected electrodes 10, 11 is set to about ½ of the thickness of the resin sealing layer 12. It is also possible that the heights of the first and second projected electrodes 10, 11 are not necessarily the same.

By electrically connecting between the upper and lower semiconductor devices 1 in the POP structure by using the first projected electrodes 10 and the second projected electrodes 11 as described above, it is possible to reduce the heights of the projected electrodes 10, 11, and based on the reduction in heights, it is possible to reduce widths (diameters in the case of the solder balls, for example) and formation pitches of the electrodes. When compared with a case where only the projected electrodes provided to the upper-side semiconductor device are used to connect between the upper and lower semiconductor devices, the size of each of the projected electrodes 10, 11 can be reduced to about ½, and further, the formation pitch can also be reduced. Therefore, it becomes possible to deal with the increase in the number of input/output pins and the increase in the number of stacking of semiconductor chips without preventing the miniaturization of semiconductor module.

When structuring the semiconductor module with the POP structure, a width of the recessed portion 13 of the lower-side semiconductor device 1 is set so that the second projected electrodes 11 of the upper-side semiconductor device 1 can be disposed within the width. For example, when it is set that the size of the first projected electrode 10 and the size of the second projected electrode 11 are approximately the same, the width of the recessed portion 13 is preferably set to 1.2 times or more the size of each of the projected electrodes 10, 11 (diameter in the case of the solder ball, for example). Accordingly, it is possible to electrically connect the first projected electrodes 10 of the lower-side semiconductor device 1 and the second projected electrodes 11 of the upper-side semiconductor device 1 in a stable manner. An upper limit of the width of the recessed portion 13 is not particularly limited. However, excessive enlargement of the width of the recessed portion 13 only leads to an increase in the size of the semiconductor device 1, so that the width of the recessed portion 13 is preferably set to 3 times or less the size of each of the projected electrodes 10, 11.

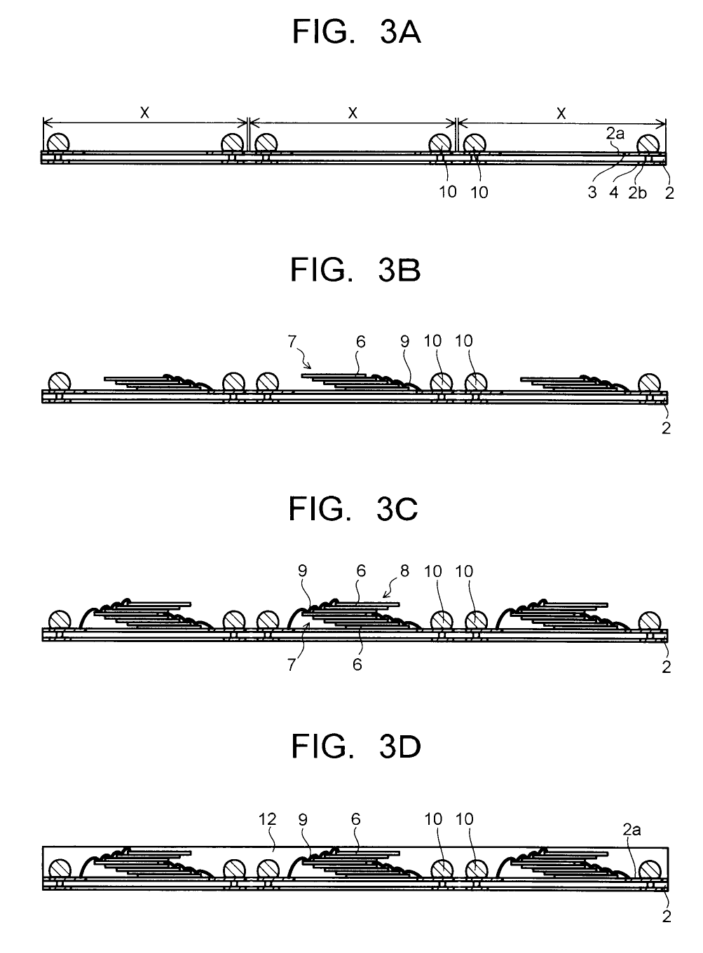

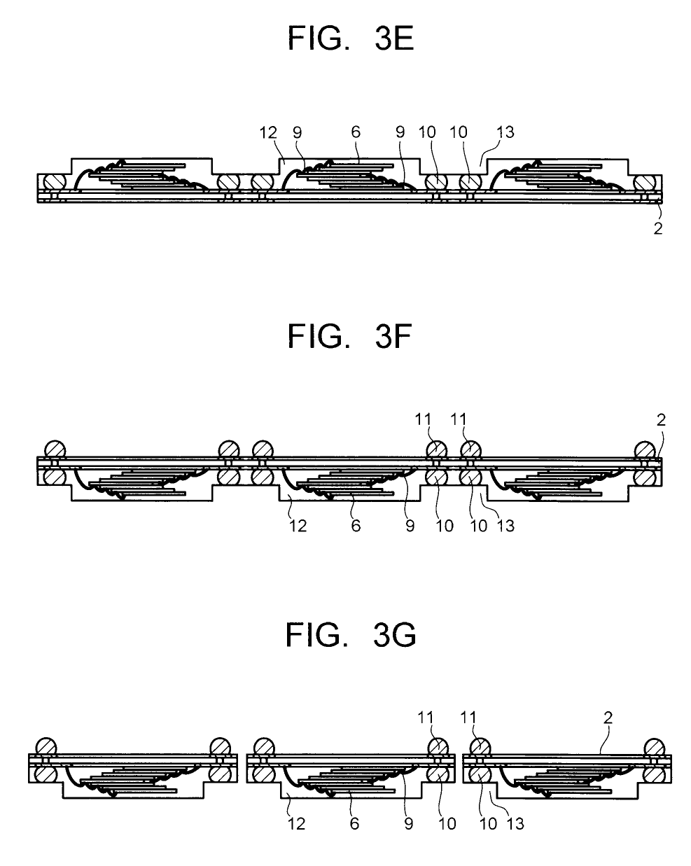

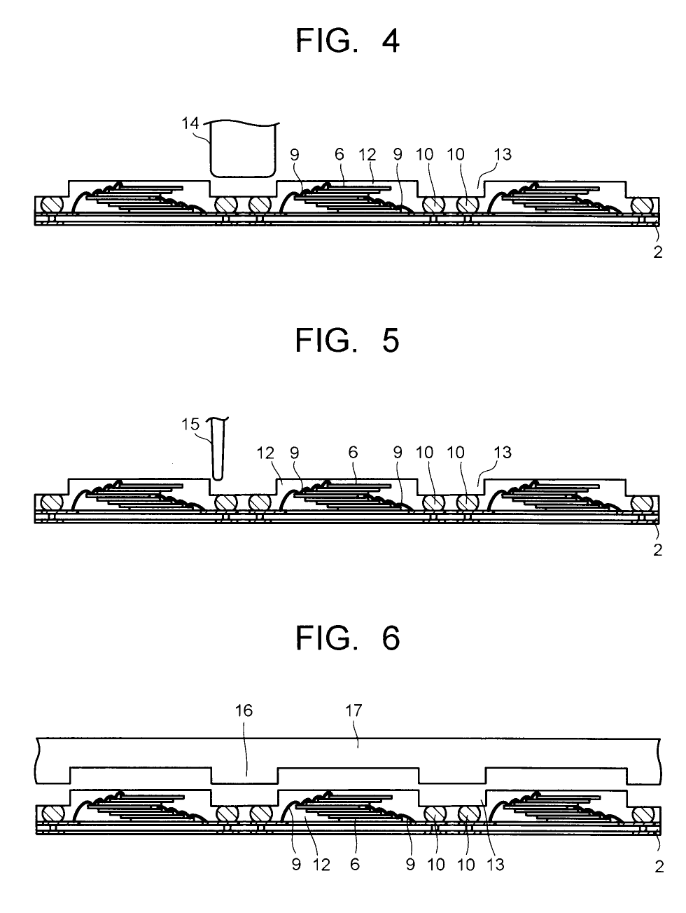

The semiconductor device 1 of the embodiment described above is manufactured in the following manner, for example. Manufacturing processes of the semiconductor device 1 will be described with reference to FIG. 3A to FIG. 3G, FIG. 4, FIG. 5 and FIG. 6. As shown in FIG. 3A, there is prepared the wiring board 2 having the first surface 2a on which the first wiring layers 3 are provided and the second surface 2b on which the second wiring layers 4 are provided. The wiring board 2 has a plurality of device forming regions X corresponding to the semiconductor devices 1. The following respective processes are performed on the plurality of device forming regions X. On the second connection pads of the first wiring layers 3 provided on the first surface 2a of the wiring board 2, the first projected electrodes 10 are formed. When applying solder balls as the first projected electrodes 10, the solder balls are placed on the second connection pads and then reflowed.

Next, as shown in FIG. 3B and FIG. 3C, the semiconductor chips 6 are mounted on the chip mounting areas provided on the first surface 2a of the wiring board 2. The mounting process of the semiconductor chips 6 is appropriately conducted in accordance with the number of stacking and the shape of stacking of the semiconductor chips 6. FIG. 3B shows a state where the plurality of semiconductor chips 6 corresponding to the first chip groups 7 are stacked in a stepped manner, and then the electrode pads of these semiconductor chips 6 and the first connection pads of the first wiring layers 3 are electrically connected by the metal wires 9 being the Au wires or the like. FIG. 3C shows a state where the plurality of semiconductor chips 6 corresponding to the second chip groups 8 are stacked, on the first chip groups 7, in a stepped manner in a direction opposite to that of the first chip groups 7, and then the electrode pads of these semiconductor chips 6 and the first connection pads of the first wiring layers 3 are electrically connected by the metal wires 9 being the Au wires or the like.

Next, as shown in FIG. 3D, on the first surface 2a of the wiring board 2, the sealing resin layer 12 that seals the semiconductor chips 6 together with the metal wires 9 and the first projected electrodes 10 is formed by molding, for example. FIG. 3D shows a case where the semiconductor chips 6 are covered by the sealing resin layer 12, and then the recessed portions 13 are formed. In this case, the sealing resin layer 12 is formed uniformly and evenly in a thickness capable of covering the semiconductor chips 6. The sealing resin layer 12 is formed entirely including cut regions between the device forming regions X. When the recessed portions 13 are formed simultaneously with the formation of the sealing resin layer 12, a shape of the sealing resin layer 12 becomes a shape shown in FIG. 3E right after the molding is performed.

Next, as shown in FIG. 3E, the recessed portions 13 each exposing a part of each of the first projected electrodes 10 are formed on the sealing resin layer 12. As shown in FIG. 4, the formation process of the recessed portion 13 is conducted by cutting (grinding) a portion of the sealing resin layer 12 corresponding to a forming position (forming region) of the first projected electrodes 10, from a surface side of the sealing resin layer 12 using a blade 14. At this time, by setting a depth of the recessed portion 13 so that a part of each of the first projected electrodes 10 is cut, a part of each of the first projected electrodes 10 is exposed to the inside of the recessed portion 13. The formation process of the recessed portion 13 by cutting the sealing resin layer 12 may also be performed by router machining or the like, instead of the blade machining.

It is also possible to conduct the formation process of the recessed portion 13 by melting the portion of the sealing resin layer 12 corresponding to the forming position (forming region) of the first projected electrodes 10 using a laser 15, for example, as shown in FIG. 5. At this time, the sealing resin layer 12 is melted to be removed to a depth at which a part of each of the first projected electrodes 10 is exposed, thereby forming the recessed portion 13 exposing a part of each of the first projected electrodes 10. Specifically, it is possible to expose a part of each of the first projected electrodes 10 to the inside of the recessed portion 13. For melting the sealing resin layer 12, local heating with the use of other than the laser 15 may also be applied.

When cutting or melting of the sealing resin layer 12 is performed, it is also possible to collectively cut or melt processing regions of the sealing resin layer 12 of the adjacent device forming regions X. In this case, after dividing the wiring board 2 into the device forming regions X, the recessed portion 13 shown in FIG. 1 is formed. By cutting or melting only the processing region of one device forming region X, after dividing the wiring board 2 into the device forming regions X, the recessed portion 13 shown in FIG. 2 is formed. The shape of the recessed portion 13 may be either one in FIG. 1 or one in FIG. 2. However, in order to reduce the formation cost of the recessed portion 13, it is preferable to collectively cut or melt the processing regions of the sealing resin layer 12 of the adjacent device forming regions X.

The formation process of the recessed portions 13 may also be conducted by forming the sealing resin layer 12 using a metal mold 17 having projected portions 16 corresponding to the recessed portions 13, as shown in FIG. 6. The recessed portions 13 are formed simultaneously with the formation of the sealing resin layer 12. Specifically, the projected portions 16 corresponding to the recessed portions 13 are previously formed on a cope (metal mold 17) used for metal molding the sealing resin. By metal molding the sealing resin layer 12 using the cope (metal mold 17) as above, it is possible to obtain the sealing resin layer 12 having the recessed portions 13. By previously adjusting heights of the projected portions 16 so that the projected portions 16 are brought into contact with the first projected electrodes 10 with a predetermined area, a part of each of the first projected electrodes 10 is exposed to the inside of the recessed portions 13 formed by the projected portions 16.

After that, as shown in FIG. 3F, the second projected electrodes 11 are formed on the fourth connection pads of the second wiring layers 4 provided on the second surface 2b of the wiring board 2. The second projected electrodes 11 are formed in a similar manner to the first projected electrodes 10. As shown in FIG. 3G, by cutting the wiring board 2 and the sealing resin layer 12 along the device forming regions 32 using blade dicing or the like, the semiconductor devices 1 separated in pieces are manufactured. FIG. 3A to FIG. 3G show the manufacturing processes of the semiconductor device 1 shown in FIG. 1. The semiconductor device 1 shown in FIG. 2 is manufactured in a similar manner to the semiconductor device 1 shown in FIG. 1 except that the shape of the recessed portion 13 is different. The shape of the recessed portion 13 is adjusted by the shape of the blade 14, the processing shape achieved by the laser 15, the shape of the projected portion 16 of the metal mold 17 or the like forming the recessed portion 13.

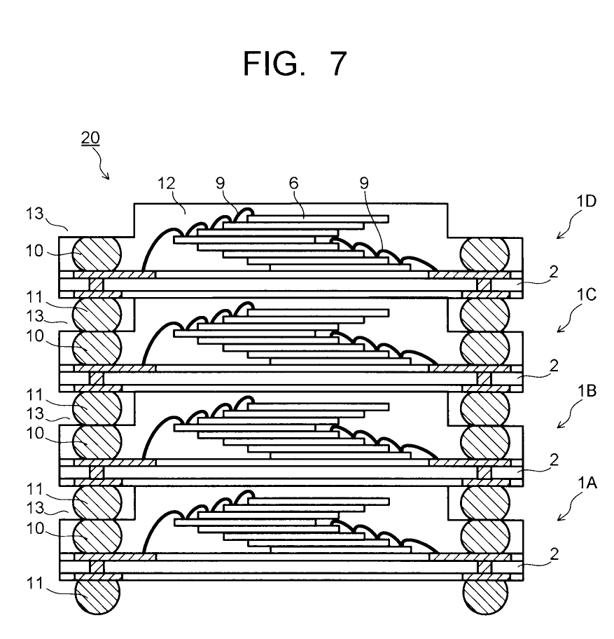

Next, a semiconductor module using the semiconductor devices 1 of the embodiment described above will be described with reference to FIG. 7 to FIG. 11. As shown in these drawings, the semiconductor module of an embodiment includes a plurality of semiconductor devices 1 of the embodiment described above. The semiconductor module has the POP structure formed by stacking the plural semiconductor devices 1. FIG. 7 shows a semiconductor module 20 according to a first embodiment. The semiconductor module 20 includes first to fourth semiconductor packages 1A to 1D. Each of the four semiconductor packages 1A to 1D uses the semiconductor device 1 of the embodiment. The number of stacking of the semiconductor devices 1 is not limited to four, and may also be four or less or four or more.

On the first semiconductor package 1A, the second semiconductor package 1B is stacked. The second projected electrodes 11 of the second semiconductor package 1B are disposed in the recessed portion 13 of the first semiconductor package 1A, and then are electrically connected to the first projected electrodes 10 of the first semiconductor package 1A. The second projected electrodes 11 of the second semiconductor package 1B are electrically connected to portions of the first projected electrodes 10 of the first semiconductor package 1A exposed to the inside of the recessed portion 13, in other words, portions of the first projected electrodes 10 exposed from the sealing resin layer 12. When the first and second projected electrodes 10, 11 are formed by the solder balls, the solder balls are electrically and mechanically connected to each other through a reflow process or the like.

On the second semiconductor package 1B, the third semiconductor package 1C is stacked. On the third semiconductor package 1C, the fourth semiconductor package 11D is stacked. The second semiconductor package 1B and the third semiconductor package 1C, and the third semiconductor package 1C and the fourth semiconductor package 1D are also electrically and mechanically connected in a similar manner. Specifically, the second projected electrodes 11 of each of the upper-side semiconductor packages (1C, 1D) are disposed in each of the recessed portions 13 of the lower-side semiconductor packages (1B, 1C), and are electrically connected to exposed portions of the first projected electrodes 10.

As described above, the second projected electrodes 11 of the upper-side semiconductor packages (1B, 1C, 1D) and the first projected electrodes 10 of the lower-side semiconductor packages (1A, 1B, 1C) are used to electrically connect between the upper and lower semiconductor devices 1 in the POP structure. Accordingly, it is possible to reduce the heights of the projected electrodes 10, 11, and based on the reduction in heights, it is possible to reduce the widths (diameters in the case of the solder balls, for example) and the formation pitches of the electrodes. When compared with a case where only the projected electrodes provided to the upper-side semiconductor device are used to connect between the upper and lower semiconductor packages, the size of each of the projected electrodes 10, 11 can be reduced to about ½, and further, the formation pitch can also be reduced.

By reducing the sizes and the formation pitches of the projected electrodes 10, 11 that connect between the upper and lower semiconductor devices 1, it is possible to increase the number of projected electrodes 10, 11 to be provided. When the shape of the semiconductor module 20 is set to be the same, it becomes possible to deal with multiplication of pins (increase in the number of input/output pins). When realizing the same number of input/output pins, it becomes possible to miniaturize the semiconductor module 20. Further, even when the number of stacking of the semiconductor chips 6 in one semiconductor device 1 is increased, in other words, when the height of the sealing resin layer 12 becomes high in accordance with the number of stacking of the semiconductor chips 6, it is possible to suppress the increase in the sizes and the formation pitches of the projected electrodes 10, 11. Therefore, it becomes possible to deal with the increase in the number of stacking of the semiconductor chips 6 without preventing the miniaturization and the multiplication of pins of the semiconductor module 20.

The semiconductor module 20 with the POP structure according to this embodiment is structured by stacking the semiconductor devices 1 with the same structure, so that the semiconductor devices 1 can be easily stacked in multiple tiers. Therefore, it is possible to easily increase the number of stacking of the semiconductor chips 6 in the semiconductor module 20 (which corresponds to a memory capacity when the semiconductor chip 6 is a memory chip, for example). By using the semiconductor devices 1 with the same structure, it is only required to prepare one type of each composing material (wiring board 2 or the like) and the molding member (metal mold or the like), which enables to reduce the manufacturing cost of the semiconductor module 20. Further, since it is possible to align warpage directions between the semiconductor devices 1, it becomes possible to improve manufacturability and reliability of the semiconductor module 20.

Since the first projected electrodes 10 to be connection terminals of the lower-side semiconductor device 1 are embedded in the sealing resin layer 12 except for the exposed portions, when compared with a case where mutual exposed projected electrodes are connected, it is possible to enhance connectivity and strength after connection between the first projected electrodes 10 and the second projected electrodes 11 to be connection terminals of the upper-side semiconductor device 1. Further, since the second projected electrodes 11 to be the connection terminals of the upper-side semiconductor device 1 are disposed in the recessed portion 13 of the lower-side semiconductor device 1, a positional accuracy with respect to the first projected electrodes 10 is easily increased. Therefore, it becomes possible to improve a connection accuracy between the upper and lower semiconductor devices 1.

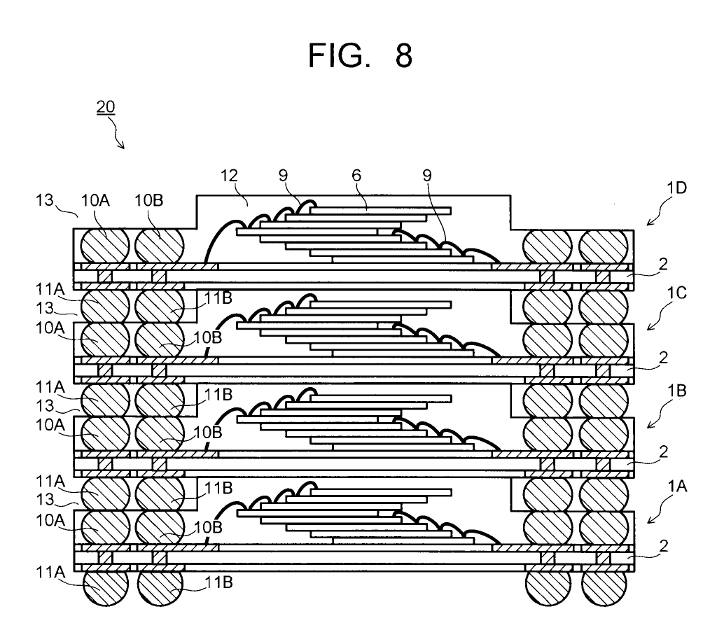

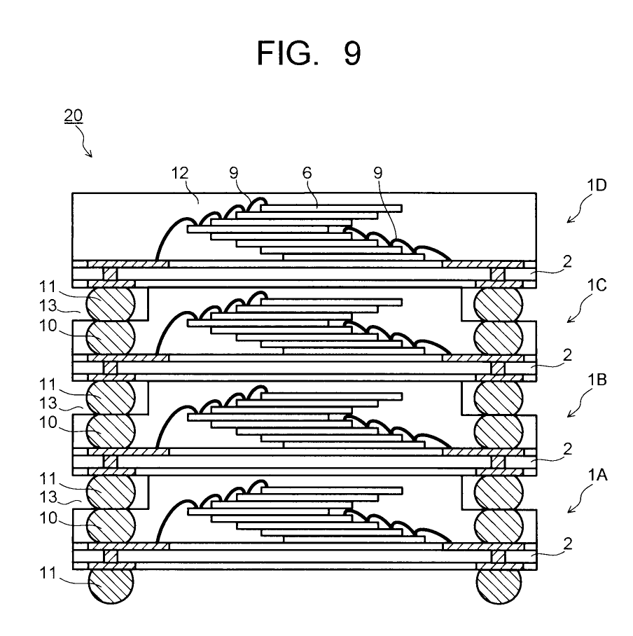

The structure of the semiconductor device 1 that forms the semiconductor module 20 can be modified in various ways. The first and second projected electrodes 10, 11 are not limited to be provided in one line around the semiconductor chips 6, and may also be provided in two lines or more around the semiconductor chips 6. FIG. 8 shows a semiconductor module 20 in which semiconductor devices 1A to 1D each having first and second projected electrodes 10A, 10B, HA, 11B formed in two lines are stacked. Since a semiconductor package is not stacked on the semiconductor package 1D positioned on the uppermost tier, it is also possible to omit the first projected electrodes 10 and the recessed portion 13, as shown in FIG. 9. It is also possible to omit only the recessed portion 13.

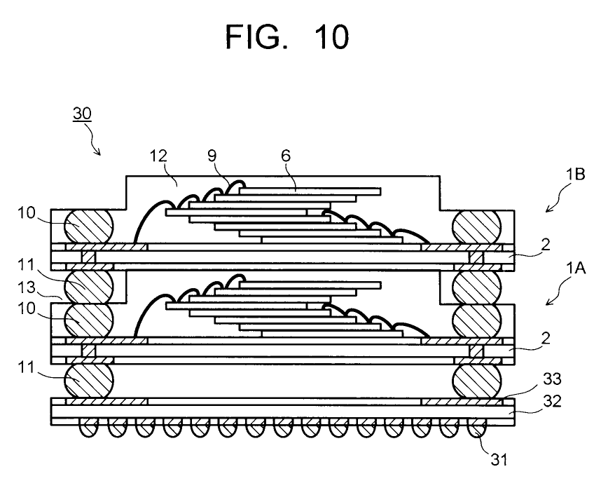

FIG. 10 shows a semiconductor module 30 according to a second embodiment. The semiconductor module 30 shown in FIG. 10 includes a first semiconductor package 1A and a second semiconductor package 1B stacked on the first semiconductor package 1A. The first and second semiconductor packages 1A, 1B have a structure similar to that of the semiconductor module 20 according to the first embodiment, and the semiconductor packages 1A and 1B are connected in a similar manner to the semiconductor module 20 according to the first embodiment. The number of stacking of the semiconductor devices 1 is not particularly limited as long as it is two or more, and may also be four or more, similar to the first embodiment.

In the semiconductor module 30 according to the second embodiment, there is disposed, on a lowermost tier, a wiring board 32 having projected electrodes 31 using solder bumps as external connection terminals. The first semiconductor package 1A and the lowermost wiring board 32 are electrically connected when the second projected electrodes 11 of the first semiconductor package 1A are connected to a wiring layer 33 on an upper surface side of the wiring board 32. The projected electrodes 31 of the wiring board 32 are arranged in a pattern different from that of the second projected electrodes 11 in the semiconductor package 1.

The second projected electrodes 11 of the semiconductor package 1 are disposed only on the outer peripheral area of the wiring board 2, so that the shape of arrangement thereof is limited. In regard to such a point, by using the lowermost wiring board 32, it is possible to increase the degree of freedom of the arrangement of the projected electrodes 31 as the external connection terminals. For example, by making the shape of arrangement of the projected electrodes 31 correspond to the existing wiring pattern, it is possible to increase versatility of the semiconductor module 30.

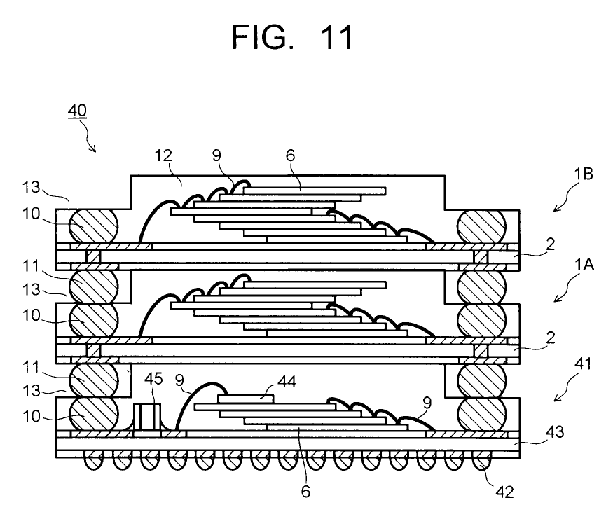

FIG. 11 shows a semiconductor module 40 according a third embodiment. The semiconductor module 40 shown in FIG. 11 includes a first semiconductor package 1A and a second semiconductor package 1B, similar to the semiconductor module 30 of the second embodiment. The structure, the number of stacking, the connection form and the like of the semiconductor packages 1A, 1B are similar to those of the second embodiment. In the semiconductor module 40 according to the third embodiment, there is disposed a dedicated semiconductor package 41 on the lowermost tier. The lowermost semiconductor package 41 includes a wiring board 43 having projected electrodes 42 arranged in a pattern different from that of the second projected electrodes 11 in the semiconductor device 1 as external connection terminals, similar to the wiring board 32 in the second embodiment.

It is also possible to increase versatility of the semiconductor module 40 also by using the lowermost semiconductor package 41. When the lowermost semiconductor package 41 is used, it is possible to dispose, in the semiconductor package 41, a semiconductor chip 44 different from the semiconductor chip 6, which is a controller chip 44 when the semiconductor chip 6 is a memory chip, for example. Further, it is also possible to dispose a chip component 45 such as a passive component in the lowermost semiconductor package 41. By using the lowermost semiconductor package 41 as described above, high function of the semiconductor module 40 can be realized. The lowermost semiconductor package 41 includes the first projected electrodes 10, the sealing resin layer 12, and the recessed portion 13 exposing the first projected electrodes 10, similar to the semiconductor packages 1A, 1B.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a wiring board having a first surface including a chip mounting area and a first wiring layer, and a second surface including a second wiring layer electrically connected to the first wiring layer;
a semiconductor chip, mounted on the first surface of the wiring board, having electrode pads;
connection members electrically connecting the first wiring layer and the electrode pads of the semiconductor chip;
first external electrodes provided on the first surface of the wiring board and electrically connected to the first wiring layer;
second external electrodes provided on the second surface of the wiring board and electrically connected to the second wiring layer; and
a sealing resin layer, provided on the first surface of the wiring board to seal the semiconductor chip together with the connection members and the first external electrodes, having a recessed portion exposing a part of each of the first external electrodes.

2. The semiconductor device according to claim 1,
wherein the first and second external electrodes include solder balls.

3. The semiconductor device according to claim 1,
wherein the recessed portion has a shape in which a side surface on an end side of the sealing resin layer is opened.

4. The semiconductor device according to claim 1,
wherein a total height of the first external electrode and the second external electrode is equal to or more than a thickness of the sealing resin layer.

5. The semiconductor device according to claim 1,
wherein each height of the first and second external electrodes is about ½ of a thickness of the resin sealing layer.

6. The semiconductor device according to claim 1,
wherein the recessed portion has a width in a range of not less than 1.2 times nor more than 3 times a size of each of the first and second external electrodes.

7. The semiconductor device according to claim 1,
wherein a plurality of the semiconductor chips are stacked on the first surface of the wiring board.

8. The semiconductor device according to claim 7,
wherein the electrode pads of the semiconductor chip located on lowermost portion among the plural semiconductor chips and the first wiring layer are connected by metal wires as the connection members, and the electrode pads of the plural semiconductor chips are connected sequentially by the metal wires.

9. A method for manufacturing a semiconductor device, comprising:
mounting a semiconductor chip having electrode pads on a chip mounting area provided on a first surface of a wiring board;
electrically connecting a first wiring layer provided on the first surface of the wiring board and the electrode pads of the semiconductor chip via connection members;
forming first external electrodes on the first surface of the wiring board, the first external electrodes being electrically connected to the first wiring layer;
forming a sealing resin layer on the first surface of the wiring board to seal the semiconductor chip together with the connection members and the first external electrodes, the sealing resin layer having a recessed portion exposing a part of each of the first external electrodes; and
forming second external electrodes on a second surface of the wiring board including a second wiring layer electrically connected to the first wiring layer, the second external electrodes being electrically connected to the second wiring layer.

10. The manufacturing method according to claim 9,
wherein the sealing resin layer forming comprises forming evenly a resin layer on the first surface of the wiring board to seal the semiconductor chip, the connection members and the first external electrodes, and forming the recessed portion by cutting a portion of the resin layer corresponding to the first external electrodes in a manner that a part of each of the first external electrodes is cut.

11. The manufacturing method according to claim 9,
wherein the sealing resin layer forming comprises forming evenly a resin layer on the first surface of the wiring board to seal the semiconductor chip, the connection members and the first external electrodes, and forming the recessed portion by melting a portion of the resin layer corresponding to the first external electrodes in a manner that a part of each of the first external electrodes is exposed.

12. The manufacturing method according to claim 9,
wherein the sealing resin layer forming comprises molding the sealing resin layer having the recessed portion by using a mold having a projected portion corresponding to the recessed portion.

13. The manufacturing method according to claim 9,
wherein the first and second external electrodes include solder balls.

14. The manufacturing method according to claim 9,
wherein a plurality of the semiconductor chips are stacked on the first surface of the wiring board.

15. A semiconductor module, comprising:
a first semiconductor package including the semiconductor device according to claim 1; and
a second semiconductor package, stacked on the first semiconductor package, including the semiconductor device according to claim 1,
wherein the second external electrodes in the second semiconductor package are disposed in the recessed portion in the first semiconductor package, and are electrically connected to portions of the first external electrodes exposed from the sealing resin layer.

16. The semiconductor module according to claim 15,
wherein the first and second external electrodes include solder balls.

17. The semiconductor module according to claim 15,
wherein a connection height of the first external electrode in the first semiconductor package and the second external electrode in the second semiconductor package is equal to or more than a thickness of the sealing resin layer in the first semiconductor package.

18. The semiconductor module according to claim 15,
wherein the first and the second semiconductor packages include the semiconductor devices with the same structure.

19. The semiconductor module according to claim 15, further comprising:
a lowermost wiring board disposed on a lower side of the first semiconductor package,
wherein the lowermost wiring board has external connection terminals arranged in a pattern different from that of the second external electrodes in the first semiconductor package, and is electrically connected to the second external electrodes in the first semiconductor package.

20. The semiconductor module according to claim 15, further comprising:
a lowermost semiconductor device disposed on a lower side of the first semiconductor package,
wherein the lowermost semiconductor device includes first external electrodes provided on a first surface of a wiring board, and external connection terminals provided on a second surface of the wiring board and arranged in a pattern different from that of the second external electrodes in the first semiconductor package, and
wherein the first external electrodes of the lowermost semiconductor device are electrically connected to the second external electrodes in the first semiconductor package.
